(19) United States
(12) Patent Application Publication
(10) Pub. No.: US 2008/0195563 A1
(43) Pub. Date: Aug. 14, 2008

(54) Solar-to-electrical energy prospecting and commercializing

(76) Inventor: Christopher James, Portland, OR (US)

Correspondence Address: ROBERT D. VARITZ, P.C., 4915 SE 33RD PLACE, PORTLAND, OR, 97202, US

(21) Appl. No.: 12/069,829

(22) Filed: Feb. 12, 2008

Related U.S. Application Data
(60) Provisional application No. 60/901,607, filed on Feb. 13, 2007.

(51) Int. Cl. G01R 29/00

(52) U.S. Cl. 705/412

(57) ABSTRACT

Solar-to-electrical-conversion energy-commercialization methodology including the steps of (a) selecting within a real-property environment a rights-holder surface area which is exposed to solar radiation, (b) applying to that area, in terms of predefined solar energy units (SOLs), an associated, potential solar-to-electrical energy output-level solar index, and a valuation therefor, based upon the manner in which solar radiation impinges the area, (c) treating the area-applied, area-associated solar index as a rights-holder property right, and (d) outwardly commercializing the selected area's applied and associated solar-index property right.

### CROSS REFERENCE TO RELATED APPLICATION

This application claims priority to the filing date of currently co-pending U.S. Provisional Application Ser. No. 60/901,607, filed Feb. 13, 2007, for “Solar Rights Standards and Public/Private Exchange System and Methodology.” The entire disclosure content of that prior-filed provisional application is hereby incorporated herein by reference.

### BACKGROUND AND SUMMARY OF THE INVENTION

This invention pertains to solar-to-electrical energy prospecting and commercializing associated with real-property rights-holder property rights. More particularly, it relates, generally speaking, to steps involving the prospecting for, and the ultimate commercializing (in various ways) of, surface areas of exposure to solar radiation which are found to exist within a real-property environment, which environment may include land mass, per se, a building structure, per se, and/or a combination of these two recognized, conventional aspects of rights-holder-associated real property.

In terms of further stating generally the nature of the present invention, and in addition to the expression thereof set forth in the title of the invention, the invention may also be described as (a) a solar-to-electrical-conversion energy-commercialization methodology, and (b) as a collateral-utility energy-commercialization method. The “collateral-utility” reference to the invention's character derives from the fact that it promotes a solar-energy asset which, at least in relation to the invention's association with surface structure in a building structure, is collateral to the other functionality(ies) assets normally furnished by surface-presenting, physical, building-structure components.

Uniquely, the present invention, as will become apparent, proposes a very useful, standardized manner of describing a newly recognized, and quite important real-property asset—namely, a quality of solar energy extraction and use potential associated with discoverable surface areas of daily solar illumination. The invention not only does this, it also sets the convenient stage for the commercialization and the transferability, using standard-measure language, of both realized and potentially realizable solar energy real-property assets—such assets being recognized as legally treatable and protectable property rights.

On a matter herein concerning certain terminology which is employed variously with reference to the invention, the terms “energy” and “power” are used interchangeably, and should be considered to possess the same meaning.

Employed within the below body of the description of the invention, references are made to a predefined power-level, or energy-level, index which is referred to herein as a SOL. A SOL is specifically predefined herein to be the level of solar-radiation power which is incident upon a 40-ft by 40-ft square surface area which lies horizontal at sea level on the 45th-parallel. A SOL may be described conveniently in any manner of power-level, or energy-level, units, whether those units are particularly expressed in terms of incident solar radiation, or, alternatively, in terms of potential electrical-power output.

Those skilled in the art should recognize that any particular predefinition of a SOL which is chosen for use in the practice of the present invention is purely a matter of invention-user choice.

A SOL, in addition to being treated herein (in accordance with implementation of the invention) as a power-level, or energy-level, index, is also, importantly and uniquely recognized to be, and is treated as, a significant, outwardly commercializable (i.e., outwardly to others than the above-mentioned rights holders) property right associated with real property. Indeed, the herein proposed SOL concept is an illustration of the earlier referred to standardized manner of describing/characterizing the solar-energy potential of real property.

Areas which are referred to herein as being areas of incident solar radiation will typically, and naturally, be characterized, over the span of normal daylight hours, as variable areas—i.e., areas which change in size, shape and location, in relation to the area-specific way in which solar radiation strikes a particular area. For example, in a completely unoccluded, sunlight-exposed area, and under normal, transitioning daylight-hour conditions, the actual, instantaneous SOL index, or rating, for that area will vary because of the fact that the angle of incidence of solar radiation which illuminates the area changes over time. There are, of course, various other reasons for SOL variation with respect to different, given areas, such as reasons associated with shading or shadowing which may exist, either all of the time, or only part of the time, during normal daylight hours. These changes, or variations, preferably are fully contemplated, i.e., fully taken into account, in the practice of the present invention, in relation to the way that a specific area's SOL index is determined. From the invention description which is presented hereinbelow, those skilled in the art will certainly understand how to accomplish SOL area-index assignment in a manner dealing with the above-mentioned illumination-area variations.

Practice of the methodology of the present invention fundamentally involves the acts of (a) prospecting for surface areas associated with real-property regarding which solar radiation is incident in different time-transitioning characteristic ways during normal daylight hours, (b) assigning a SOL index to each such area, (c) recognizing that each such assigned SOL index is a rights-holder property right which may be valued, and (d) outwardly monetizing, or commercializing, these area-specific SOL indices in various of different ways. For example, with regard to a particular real-property environment, or region, the presence of areas having assigned SOL indices, or ratings, accommodates the sales, licensing, or leasing, etc., of such property-area assets to third-parties. In other words, and speaking about this concept in terms of a building structure possessing surface areas which may be given SOL ratings, sale of such a building structure may include a sale value component which is based upon a cumulative SOL index for that building structure.

Commercialization of SOL rights may also involve equipping SOL-indexed areas with any one of a number of different appropriate forms of solar-to-electrical conversion structure that enables the direct outputting of commercializable electrical energy. Further, and if desired, the invention contemplates a methodology with respect to which solar-to-electrical conversion instrumentalities may be designed with what is referred herein as a follow-sunlight motion behavior, which behavior will naturally tend to flatten or shrink the variation in instantaneous SOL value associated with an area, so as, in effect, to maximize conversion-to-electrical output potential for a SOL area so equipped.

The invention, now to be described in greater detail below, thus dramatically opens a door for the commercialization of, following prospecting for, solar radiation which is incident collaterally on different surface areas that reside within rights-holder-based real property.

These and other important features of the present invention will become more fully apparent as the detailed description of the invention which follows below is read in conjunction with the accompanying drawings.

### DESCRIPTION OF THE DRAWINGS

FIG. 1 is a high-level, schematic and stylized illustration of the methodology of the present invention practiced in conjunction with a real-property environment which includes both sunlight-exposed ground space, and a building structure possessing various surface areas, whether above ground or not, that are illuminated with solar radiation during normal daytime hours. In particular, FIG. 1, relative to its left and right sides (illustrating time-of-day changes), illustrates a condition of time transition associated with solar radiation incident upon the real property generally illustrated in FIG. 1. Among other things, this figure illustrates, regarding two, pictured, sunlight-illuminated areas, an angle of sunlight incidence change.

FIG. 2 is also a high-level, schematic and stylized, left-side/right-side, time-of-day-change drawing illustrating the concept that a SOL-indexed area may be equipped with solar-to-electrical conversion structure which is designed to offer follow-sunlight motion behavior.

FIGS. 3-6, inclusive, additionally are high-level, block/schematic diagrams, including blocks labeled with text, illustrating several different ways of visualizing the steps involved in practicing the methodology of the present invention.

### DETAILED DESCRIPTION OF THE INVENTION

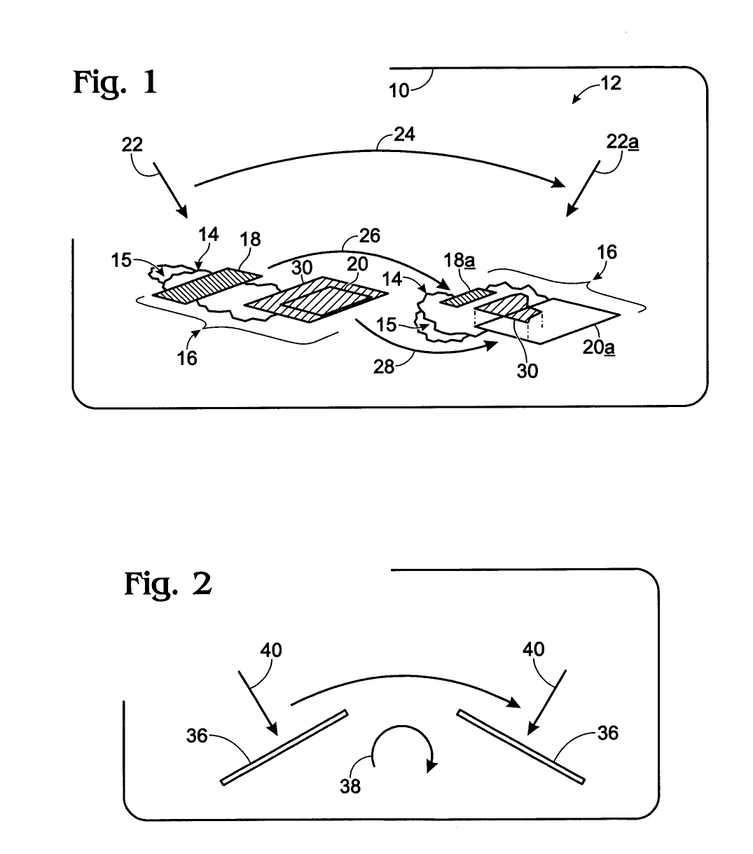

Turning attention now to the drawings, and beginning with FIG. 1, indicated generally by an embracing bracket 10 is a rights-holder real-property environment 12 including a building structure shown fragmentarily at 14, and underlying ground shown fragmentarily at 15 to which building structure 14 is conventionally anchored. Focusing herein principally on building structure 14 for the purpose of describing a preferred and best-mode manner of practicing the present invention, this structure has been found, by an invention step, or process, referred to as prospecting, to include, in a region 16, a pair of spaced-apart surface areas 18, 20 that are illuminated by, or exposed to, solar radiation, such as that represented by a sunlight-incidence directional arrow 22.

FIG. 1 has been constructed with differentiated left and right sides to illustrate, in a general fashion, how the illumination-by-sunlight characteristics of areas 18, 20, and how the sizes, shapes and relative locations of these two areas, change throughout a time span of normal, daytime hours. To this end, sunlight-illuminated areas 18, 20, and sunlight-incidence directional arrow 22, are shown adjacent the left side of FIG. 1 at a point in time which is early during normal daylight hours. As can be seen, areas 18, 20 have been illustrated with different specific shapes and sizes, generally rectangular in nature.

Later in the day, and as is indicated by a broad, curved, right-pointing, “time-of-day-change” arrow 24, sunshine-illumination incidence direction is now as indicated by moved arrow 22 as that arrow is pictured on the right side of FIG. 1. The right side of this figure also illustrates, generally, changes that have occurred in the respective sizes, shapes and relative-position conditions of areas 18, 20. More specifically, illuminated area 18 has now diminished in size, and changed in shape and position (within region 16), as is indicated by a right-pointing, curved, “time-of-day-change” arrow 26, and area 20 has enlarged, and has also changed in shape and position (within region 16) as indicated by a right-pointing, curved, “time-of-day-change” arrow 28.

Such illumination-area changes in shape, size and location are well understood as being caused by normal relative motion between the earth and the sun.

In order to describe one modified way in which commercialization, in accordance with practice of the invention, may be performed, further generally illustrated in, and/or described now (without specific picturing) herein with respect to FIG. 1 is that areas 18, 20 have been overlay-equipped with solar-to-electrical energy conversion structure of any appropriate nature. In FIG. 1, in order to minimize drawing clutter therein, only that energy conversion structure which has been provided for association with area 20 is specifically presented in FIG. 1—this structure being shown at 30. Preferably, equipping of a sunlight-illumination area, such as areas 18, 20, is done in such a fashion that the perimeter shape of the employed conversion structure is designed, and the conversion structure, per se, is positioned, to allow for energy conversion to take place under circumstances wherein the actual perimeter of sunlight illumination is always fully associated with the relevant conversion-surface-area of the conversion structure. In the illustrations provided in FIG. 1, conversion structure 30 has been so designed, and while this structure, as can be seen, is broader in extent laterally than its associated illumination area 20, as such area is pictured on the left side of FIG. 1, it is substantially laterally exactly co-extensive with the lateral perimeter of that size-changed (increased) area as shown on the right side of FIG. 1.

In accordance with the preferred practice of the methodology of the present invention, a real-property environment (building(s) and ground) is subjected to prospecting for sunlight-illumination areas, such as areas 18, 20. With regard to such areas which, through prospecting, become identified, and which are ultimately selected for use in accordance with the present invention, and by any appropriate technique, an evaluation is made by assessing the transitioning characteristics of area illumination for such selected areas, and this activity is intended to yield (i.e., lead to) an area assignment of what was described earlier herein as a SOL index. In other words, each prospected illumination area selected for use in the practice of the present invention is characterized with a SOL index number which basically describes, among other things, the potential for extracting solar-to-electrical converted energy derived from the relevant area, or areas.

The index number for a selected area, and an “accumulated” index summation number associated with plural, selected, SOL-indexed illumination areas, is/are treated as, and recognized to be, property-right subject matter (i.e., property right(s)) which are associated with real-property ownership rights held by the relevant, real-property environment people who are the rights holders regarding that environment. These identified and selected areas—identified through prospecting for them—and the ultimately associated and assigned SOL indices related thereto, represent valuable commercialization assets which may be commercialized in a very wide variety of manners, such as by sale, leasing, licensing, etc. Outward commercialization may take place either with reference to SOL-indexed area assets, per se, or by selling (for example) electrical power generated by and from SOL-indexed areas which have been appropriately equipped with energy conversion structure of the kind(s) mentioned above.

As was suggested earlier herein, in any suitable manner with respect to the assigning of a SOL index number to a particular, prospected area of illumination, such assigning may be may be done in any appropriate, user-selectable fashion which thoughtfully takes into account SOL-index variation over the span of normal daytime time.

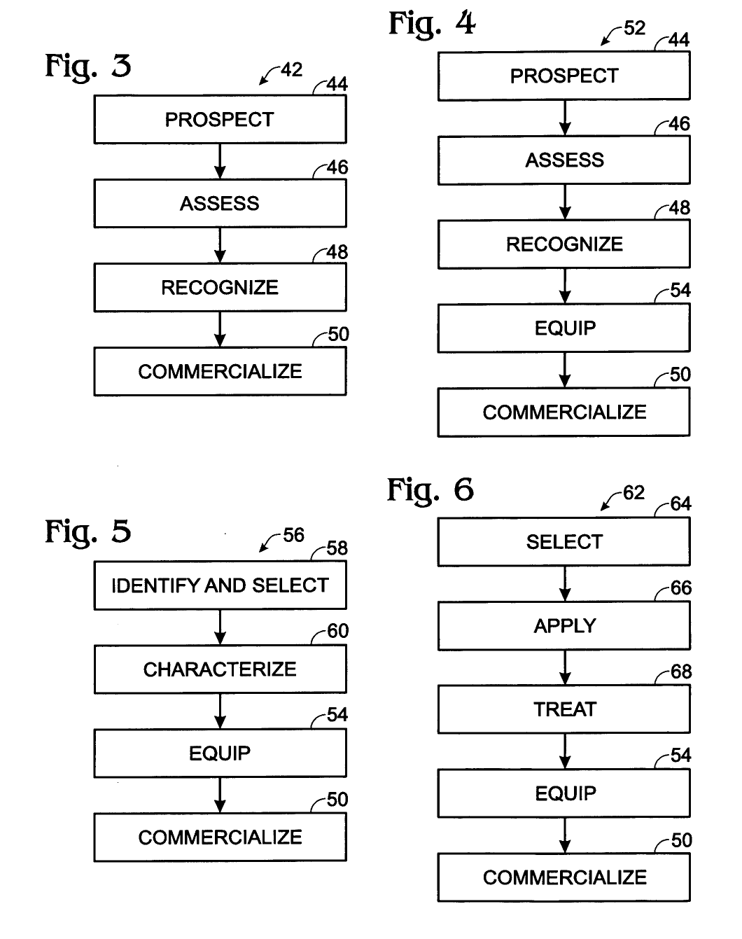

Turning attention to now briefly to FIG. 2, what is illustrated here, in a left-side/right-side, time-of-day-change drawing, is an approach that may be employed in accordance with another modified manner of practicing the invention. In this modification, a particular sunlight-illumination area is equipped with energy-conversion structure 36 which possesses an appropriately computer-and-motor-controlled motion instrumentality which operates continuously to maintain the “aim” of the structure as precisely as possible at the direction of “incoming” sunlight. Structure 36 is also referred to herein as a structure which features follow-sunlight motion behavior. Thus, FIG. 2 illustrates a quite simple and idealized condition wherein solar-to-electrical conversion structure 36 is equipped, as illustrated by curled arrow 38, to be rotated/angulated so as to maintain the instantaneous sunlight angle of incidence, represented by an arrow 40, in a condition which is substantially normal to the sunlight-receiving surface in structure 36. One should understand that, while this highly idealized (FIG. 3) situation may not frequently be fully obtainable, some form of follow-sunlight motion in energy conversion equipment will always be effective, from moment-to-moment, essentially to maximize the amount of solar-to-electrical power conversion which may take place.

In specific accordance with a preferred and best-mode manner of practicing the present invention, a real-property environment is subjected to prospecting to identify, and ultimately to select, surface areas therein which, during normal daytime hours, are illuminated by sunlight. These areas may, as illustrations, take the form of included, sunlight-exposed building-structure surface areas, and/or ground surface areas, lying at any elevation within the mentioned environment. Selected areas are energy-characterized with, and in terms of, predetermined, standardized solar energy units, referred to herein as SOLs, as a way of describing, and ultimately valuing, their respective potentials for the harvesting and commercializing of solar-to-electrical power, or energy. These areas, and their associated SOL indices are, in the methodologic context of the present invention, formally recognized and treated as being owned, and otherwise traditional, property rights which, under the long-established laws regarding such rights, may function completely normally in the usual flow of commerce. The proposed invention methodology offers an important and significant way to recognize an appreciable real increase in commercializable real-property values.

What one can therefore readily see from the invention description just presented above is that its methodology opens the door to the recognition and commercial exploitation of a new kind of commercially valuable real property right/asset which is based upon the presence of various surface areas in real property, such as building-surface areas, and/or ground-surface areas, that are illuminated by sunlight. And so, for example, a building structure with respect to which prospecting has taken place to identify areas of sunlight illumination, with SOL indices appropriately applied to these areas, is a building structure the sale of which may include the sale/or-otherwise-transfer of SOL-index rights. As was suggested earlier herein, outright sale is certainly not the only legal-transfer methodology for commercializing sunlight illumination areas as described herein. Other legal mechanisms, recognized by those associated with exploiting the commercial possibilities of real property, may just as well be employed. Certainly, one way importantly for commercializing prospected areas of sunlight illumination involves equipping selected ones of those areas with solar-to-electrical conversion structure of any nature, and selling “converted-to” electrical power.

A standardized SOL measure of solar-energy potential for real property will allow the conducting of real-property commercial activities in useful terms such as: “This property, in addition to other features and assets, includes three-and-one-half SOLs,” etc.

FIGS. 3-6 in the drawings, to which attention is now directed, generally illustrate several different ways of characterizing, in words and in flow charts, the basic methodologic features of the present invention.

In accordance with what is shown at 42 in FIG. 3, the invention may be described as solar-to-electrical-conversion energy-commercialization methodology associated with real-property rights-holder property rights, and including the steps of: (a) prospecting for areas of exposure to solar radiation within a real-property environment (block 44); (b) for each of selected ones of such areas, assessing, in terms of predefined solar energy units (SOLs), the potential solar-to-electrical conversion electrical-energy output obtainable from the area based upon area-specific-associated solar-radiation exposure characteristics (block 46); (c) recognizing the SOL as a rights-holder property right (block 48); and (d), in association with the mentioned rights-holder property rights, outwardly commercializing the assessed, area-specific SOLs (block 50).

As illustrated at 52 in FIG. 4, another way of viewing the methodology of the present invention is to see it as including all of the steps illustrated in FIG. 3 augmented by an initial step, shown as a block 54 in FIG. 4, involving equipping at least one of the selected areas with solar-to-electrical energy conversion structure.

Still with reference to the methodology of the invention as expressed in FIG. 4, a modified form of the invention is one wherein the equipping step includes installing solar-to-electrical energy conversion structure of a type which additionally features follow-sunlight motion behavior.

FIG. 5 illustrates at 56 yet another way of characterizing the present invention. In accordance with this view of the invention, the same takes the form of a collateral-utility energy-commercialization method for monetizing, relative to a property-rights-associated real-property environment including building structure, selected building-structure surface areas which are illuminated by sunlight during normal daytime hours including the steps of: (a) identifying and selecting such areas (block 58); (b) characterizing each selected area so as to ascribe to it, in terms of predefined solar energy units (SOLs), an area-specific solar-to-electrical energy output-level solar index, and a valuation therefor, based upon the specific way in which sunlight nominally illuminates the area during the mentioned daytime hours (block 60); (c) equipping selected areas with solar-to-electrical energy conversion structure operable to output electrical energy when the associated areas are illuminated by sunlight (previously mentioned block 54); and (d), utilizing appropriate law-recognized transfer modalities, including, but not limited to, area-specific deeds, sales, rentals, leases, licenses, trades and privileges, commercializing to interested parties the SOLs associated with the selected areas (previously mentioned block 50).

Still a further way of viewing the invention is pictured at 62 in FIG. 6. In accordance with this view of the invention, the same takes the form of solar-to-electrical-conversion energy-commercialization methodology including the steps of: (a) selecting, within a real-property environment including building structure, a rights-holder building-surface area which is exposed to solar radiation (block 64); (b) applying to the selected area, in terms of predefined solar energy units (SOLs), an associated, potential solar-to-electrical energy output-level solar index, and a valuation therefor, based upon the manner in which solar radiation impinges the area (block 66); (c) treating the area-applied and area-associated solar index as a rights-holder property right (block 68); (d) equipping the selected area with solar-to-electrical energy conversion structure (previously mentioned block 54); and (e), outwardly commercializing the selected area's applied and associated solar-index property right (previously mentioned block 50).

Yet one more way of visualizing a cooperative organization of steps in the methodology of the present invention, is to see this organization as including the steps of: (a) establishing a SOL index as a real-property right; (b) conducting prospecting in a real-property environment to detect therein nominal SOL-capable surface areas which exist during a normal daytime time span; (c) characterizing each of such detected areas with a respective SOL index whose value, in relation to such a time span, reflects both (1) specific-area size, shape and location changes, and (2) specific angle-of-sunlight-incidence changes: and (d), commercializing the area-associated SOL index values.

Accordingly, a unique way of recognizing and monetizing (commercializing) a new form of real-property right, referred to herein with a value-standardizing solar-energy measure such as a SOL, or as a collection of SOLs, has been described and illustrated herein. This right, expressible in standardized terminology, attaches to real-property assets that take the form of carefully prospected and clearly identified, sunlight-exposed real-property surface areas which have a dynamic, time-transitional quality about them. The right, and its value, rest upon the specific sizes of such sunlight-illumination transition areas, per se, and not upon arbitrarily chosen and conventionally implemented surface areas of pre-sized solar-to-electrical conversion panels. Put another way, the right and its value exist in relation to structure which is completely independent of the sizes and shapes of conventional, so-called solar panels. Variations and modifications of the basic methodology of the invention, some of which have been illustrated and described herein, are recognizably possible, and it is intended that all such variations and modifications will come within the scopes of the claims to invention presented herein.

I claim:

1. Solar-to-electrical-conversion energy-commercialization methodology associated with real-property rights-holder property rights comprising
with regard to a particular real-property environment, prospecting for areas therein of exposure to solar radiation,
for each of selected ones of such areas, assessing, in terms of predefined solar energy units (SOLs), the potential solar-to-electrical conversion electrical-energy output level obtainable from the area based upon area-specific-associated solar-radiation exposure characteristics,
recognizing the SOL as a rights-holder property right, and
in association with the mentioned rights-holder property rights, outwardly commercializing the assessed, area-specific SOLs.

2. The methodology of claim 1, with respect to which the mentioned areas are not necessarily above ground level.

3. The methodology of claim 1 which further comprises equipping at least one of the mentioned, selected areas with solar-to-electrical energy conversion structure.

4. The methodology of claim 4, wherein said equipping includes installing conversion structure of the type mentioned which additionally features follow-sunlight motion behavior.

5. The methodology of claim 1 which further comprises predefining a SOL.

6. A collateral-utility energy-commercialization method for monetizing, relative to a property-rights-associated real-property environment including building structure, selected building-structure surface areas which are illuminated by sunlight during normal daytime hours, said method comprising
identifying and selecting such areas,
characterizing each selected area so as to ascribe to it, in terms of predefined solar energy units (SOLs), an area-specific solar-to-electrical energy output-level solar index, and a valuation therefor, based upon the specific way in which sunlight nominally illuminates the area during the mentioned hours,
equipping selected areas with solar-to-electrical energy conversion structure operable to output electrical energy when the associated areas are illuminated by sunlight, and
utilizing appropriate law-recognized transfer modalities, including, but not limited to, area-specific deeds, sales, rentals, leases, licenses, trades and privileges, commercializing to interested parties the SOLs associated with the selected areas.

7. Solar-to-electrical-conversion energy-commercialization methodology comprising
selecting, within a real-property environment including building structure, a rights-holder building-surface area which is exposed to solar radiation,
applying to the selected area, in terms of predefined solar energy units (SOLs), an associated, potential solar-to-electrical energy output-level solar index, and a valuation therefor, based upon the manner in which solar radiation impinges the area,
treating the area-applied, area-associated solar index as a rights-holder property right,
equipping the selected area with solar-to-electrical energy conversion structure, and
outwardly commercializing the selected area's applied and associated solar-index property right.
